(19) United States
(12) Patent Application Publication
(10) Pub. No.: US 2009/0308377 A1
(43) Pub. Date: Dec. 17, 2009

(54) OPTICAL SYSTEM WITH A TRANSPARENT SPHERE AND USE OF THE SAME

(76) Inventor: Jurgen Kleinwaechter, Kandern (DE)

Correspondence Address: COLLARD & ROE, P.C., 1077 NORTHERN BOULEVARD, ROSLYN, NY, 11576, US

(21) Appl. No.: 12/311,062

(22) PCT Filed: Sep. 19, 2007
(86) PCT No.: PCT/DE2007/001680

§ 371 Date: Jul. 31, 2009

(30) Foreign Application Priority Data
Sep. 19, 2006 (DE) 10 2006 044 601.1

(51) Int. Cl. F24J 2/08; G02B 3/00; G02B 3/12; H01L 31/00; F24J 2/38; H01L 31/052; G02B 7/02

(52) U.S. Cl. 126/605; 359/664; 359/665; 136/252; 136/259; 126/611; 136/246; 359/814

(57) ABSTRACT

The invention relates to an optical system comprising a transparent ball, particularly filled with a transparent liquid. Direct sunlight that is incident on the ball area exposed to the sun is reflected on the opposite, internal face of the hollow ball by means of a rotary mirror in such a way that the focus of the radiation field is reproduced in the center of the hollow ball. Solar converters can thus be statically disposed in the center of the hollow ball and are preferably provided with only one twisting means in order to permanently keep the solar converters in an ideal alignment relative to the focused sunlight.

The invention relates to a optical system with a transparent sphere as well as the use of an optical system with a transparent sphere.

Per definition transparent spheres concentrate the sunlight with spherical aberration. However, sphere-symmetrical spherical lens systems have, compared with any other shapes of reflecting or refractive concentrating mirrors or lenses, one outstanding characteristic as regards a moving radiation source:

No matter from which direction the light from the source falls upon the optical system, the caustic surface in the focal plane of the moving focal point is always the same.

From early on meteorologists have utilized this fact in that they mapped the always identically shaped focal spot of a stationary glass sphere onto a hollow spherical cap extending on the rear side of the sphere facing away from the sun over a distance equal to the focal depth. The material of the spherical cap always blackens when the sun shines so that the number of focal spots or the length of the thereby produced “focal lines” represents a direct measure for the duration of the sunshine.

Other developers, for instance those working with the French scientist F. Authier, Laboratoire D'Astronomise spatiale, Marseille, developed stationary large spherical internally mirrored half shells and had the receivers move along orbits at a distance of half the radius in such a way that they always lie in the focal point of the lens system (the program is called Pericles: Production d'Electricité en Region Isolée par Concentration Limité d'Energie Solaire).

The inventor of the present patent application has already published numerous other inventions in the field of lens systems, as for example in the WO 2007/095934 A and the WO 2000/20805 A.

The invention is based on the requirement to improve the existing technology.

According to a first aspect of the invention this requirement is met by an optical system with a transparent sphere, whereby the optical system comprises a dynamic lens system for concentrating moving sunlight at a locally static focal point.

To begin with it should be explained that the term “dynamic lens system” is understood to be an optical system which, as regards its position, alignment and/or shape is variable thereby fixing the location of the focal point whilst the sunlight moves. A “locally static” focal point does not need to be exactly stationary in a mathematical-physical sense. Rather it is sufficient if the focal point is substantially stationary. The expert addressed here, i.e. an engineer, would assess this by way of the relation between a possible displacement of the focal point and the overall outer dimensions of the optical system. A focal point can certainly be called a locally static focal point if the focal point moves by no more than one fifth, in particular one tenth of the diameter of the transparent sphere during the time the sun “moves”.

With previously known lens systems the focal point moves along long paths. Therefore solar converters also, for example liquid pipes or solar cells, need to be present on long paths or be tracked, in order to make the best possible use of the sunlight. This leads not only to a considerable space requirement but also to complicated connecting elements between the solar converter and the lens system, with these elements having to be moved as well. The aspect of the invention presented here is designed to alleviate this problem in that it always concentrates the sunlight in the same spot despite the fact that the direction of the incident light changes. Only at this point need solar converters be installed.

Even if the direction of the rays within the proposed lens system towards the stationary focal point changes while the sun “moves”, a solar converter provided at the static focal point may remain static.

It is proposed, however, that the solar converter has a rotating means. In particular, embodiments are feasible, in which the solar converter is hit permanently ideally by the sun rays by performing a rotation.

A rotating means of this kind preferably comprises a connecting strut connecting it with the dynamic lens system. Using a connecting strut between the dynamic lens system and the solar converter will readily ensure that these two components are at a constant angle to each other. Then all that remains is to find the correct alignment for the dynamic lens system so that the supply of light rays to the solar converter is ideal.

Preferably a tracking device is provided for the dynamic lens system. The invention can be realized in a particularly simple manner by designing the transparent sphere so as to be stationary and static. Since the dynamic lens system is to be moved, a tracking device is proposed in order to ensure the tracking of the dynamic lens system with regard to the actual position of the sun. The tracking device can be constructed mechanically or mechatronically using very simple means. In particular the tracking device may comprise mechanical energy transmitters, a motor and a microprocessor. The microprocessor is preferably in an electronic data processing system. This may be networked thus allowing the tracking geometry for the dynamic lens system to be changed, as necessary, by remote control. This enables different locations to be finely adjusted.

Preferably the tracking device is set so that it aligns a normal line vector of the dynamic lens system with the sun. A normal line vector is understood to be an imagined spatial vector which is centrally aligned on the dynamic lens system in such a way that it extends vertically to a principal mounting plane of the dynamic lens system. The shape of the dynamic lens system is therefore imagined as being rather shallow, shell-shaped, square or round, plane or curved. Such geometries comprise a principal mounting plane. In the case of curved geometries a plane surface supported on the rim of the camber could be considered.

Alternatively and in addition to tracking the normal line vector in direction of the sun it is advantageous if the tracking device is adjusted in such a way that it guides the dynamic lens system with regard to the incident sunlight beyond a central point of the transparent sphere. As already explained, a transparent sphere is a very good means for effecting a predictable mapping of the sunlight, even if the direction of the incident rays changes. The shape of the focal spot is constant as regards the central direction of the incident light. If the dynamic lens system is therefore guided beyond the central point of the transparent sphere the shape of the focal spot is always constant. This makes it easier to define the shape of the dynamic lens system.

It is proposed that a normal line vector of the dynamic lens system points to a central point of the transparent sphere. If this is the case it becomes very easy to make this point also the static focal point.

It is generally advantageous if the static focal point lies within the transparent sphere. Fittings such as in particular solar converters, can be installed here, where they are protected by the transparent sphere and thus have a long lifespan.

It should be expressly pointed out that an optical system with a transparent sphere and a dynamic lens system is advantageous, irrespective of any other features of the invention presented here, provided a tracking device for the dynamic lens system is provided which guides the dynamic lens system in such a way that whilst the rays of the sun move the focal point is retained within the transparent sphere.

In a particularly preferred embodiment the static focal point lies in a central point of the transparent sphere. A solar converter installed here is a relatively long distance away from the outer envelope of the transparent sphere and is therefore not in the way, while the dynamic lens system is guided essentially along the outer envelope. Guidance of the dynamic lens system along the outer envelope is considered to be an advantage by the inventor. Besides it is extremely easy to install stationary solar converters in the central point of the sphere.

Preferably the dynamic lens system comprises a deflecting mirror. A mirror is an inexpensive item to manufacture and very light if suitably constructed. Besides, installing the mirror on the side facing away from the sunlight is very good because the dynamic lens system in this case does not lie in the path of the incident light.

Preferably the circumference of the dynamic lens system is circular. In particular a dynamic lens system comes to mind which has a spherical or curved surface a section of which is mirrored. This adapts well to the spherical outer envelope of the transparent sphere.

The tracking device preferably comprises a contactless drive, in particular an outer magnet and an inner magnet. With a contactless drive part of the tracking device may be arranged outside the transparent sphere, whilst another part is arranged inside the sphere. This prolongs the lifespan of the drive since at least that part which is arranged inside the transparent sphere is well protected from environmental influences.

It should be pointed out that an optical system with a transparent sphere and a dynamic lens system with a tracking device, whereby the tracking device comprises a contactless drive, in particular an external magnet or an internal magnet, is advantageous irrespective of all other features of the present invention.

Preferably the tracking device comprises a shell. A shell readily adapts from the outside to the outer envelope of the transparent sphere.

In a technically much further developed embodiment the tracking device comprises a plurality of controllable external magnets. The external magnets may be activated either mechanically allowing them to be moved closer to or further away from the external shell in order to increase the magnetic influence upon the inside area of the transparent sphere, or the external magnets may be electronically controlled in order to magnetize selected points without moving the external magnets locally.

It should be pointed out that the internal magnet does not necessarily have to be an active magnet. Rather it suffices if it reacts magnetically to an externally applied magnetic field. For example, any given iron core may be attached on one side of the spherical envelope.

Preferably—and an independent advantage according to a third aspect of the present invention—the transparent sphere, on its inside, comprises a dynamic lens system, which together with dynamic fittings forms a center of gravity situated in a central point of the transparent sphere. This aspect of the invention is based on the idea that the dynamic lens system will comprise further fittings which are required, for example, for guidance of the dynamic lens system within the transparent sphere or which, for example, effect a coupling with the solar converter. As a result the entire dynamically moved system grows to a relatively large mass within the transparent sphere. If the center of gravity of this dynamically moved system lies in the central point of the sphere, it can be made to rotate about the central point using a relatively small amount of energy.

It is proposed that the transparent sphere be filled with a liquid. This liquid has a refractive index which is different from that of air or vacuum so that the path of the rays of the sunlight within the transparent sphere can be influenced by the selection of the liquid.

The internal liquid should have a high optical refractive index, be highly transparent in the desired spectral range, of low viscosity and resistant to radiation.

Liquids suitable as internal liquids are liquids such as water, silicone oils, ethylene or propylene glycols as well as other commercially available liquids such as used in waveguides with liquid cores, for example.

The following are two examples as to how liquids should be selected:

If a silicone solar cell with the usable light spectrum which finishes above 1.1 μm, is to be utilized as a solar converter, water is a good choice because it is highly transparent to 1.1 μm, but highly absorbent for larger wavelengths. Similar criteria apply to an optical waveguide which shall direct concentrated visible light into spaces, whilst keeping out heat. Since the human eye detects light up to 0.74 μm, substances should be added to the water in this case which move its absorption edge from 1.1 μm to approx. 0.8 μm.

If a combination of different semi-conductors shall be used as solar converters, for example so-called triple-junction cells made of gallium phosphide, gallium arsenide and germanium, the transparency window must go beyond 2 μm. Silicone oils or polyethylene glycol (PEG) are particularly well suited for this purpose.

In principle, the closer the optical refractive index of the liquid medium is to 2, the smaller is the image of the sun on the rear spherical cap. At N=2 the focal point of the spherical lens system lies on the spherical cap.

Since the spherical lens system, like any highly-concentrating lens system, projects only direct sunlight into the focus, the diffuse share of the radiation from the sphere-half facing away from the sun enters into the space beyond it, where it can be used for the purpose of illuminating plants and people. Advantageously, in order to maximize this diffuse light flow, the chosen liquids should have a very high refractive index, since this will reduce the size of the deflecting mirror which reflects part of this radiation back.

Preferably a fitting in the transparent sphere has an optical refractive index which corresponds to that of the liquid. The incident rays guided inside the transparent sphere then pass through all fittings without any optical impairment.

Preferably—and an independent advantage according to a fourth aspect of the invention—the transparent sphere is filled with a liquid, while the optical system comprises a lens system for concentrating moving sunlight at a solar converter, and whereby the solar converter is surrounded by liquid. This leads to effective cooling for the solar converter by the liquid.

It is proposed to provide a feed line to an external heat exchanger. If the liquid—or generally the medium—in the sphere is redirected and pumped to an external heat exchanger, both electrical current and available heat can be generated.

It has already been pointed out that an optical system of the above-described construction type is well suited for utilizing direct sunlight—in particular for generating current and hot water—and for transmitting diffuse sunlight. Thus in a preferred further development of the invention it is envisaged to use a plurality of such optical systems as an outer envelope of a building. A special idea would be to use it as an envelope for a greenhouse or for a roof or facade of an office or residential building.

As soon as a plurality of optical systems is combined, it is advantageous if a plurality of tracking devices comprises one jointly used mechanical power generator. In the ideal case a single motor could be used for tracking all dynamic lens systems.

Also, with a plurality of optical systems it is proposed to connect the transparent spheres with each other in such a way that liquid can be redirected in order to dissipate the heat in a purposeful manner.

The invention will now be described in detail by way of some embodiments and functional principles with reference to the drawing. Functionally identical components are identified by identical reference symbols.

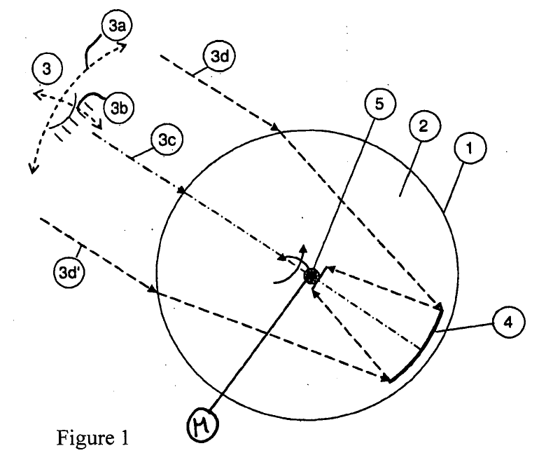

FIG. 1 schematically shows a first embodiment of a transparent sphere with a circulating mirror,

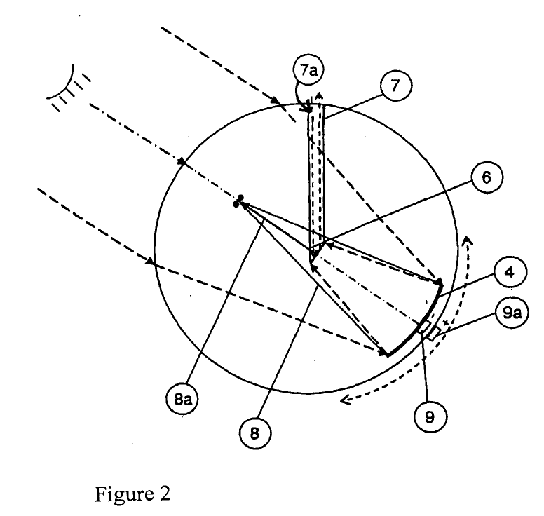

FIG. 2 schematically shows a second embodiment of a hollow strut and a magnetic drive,

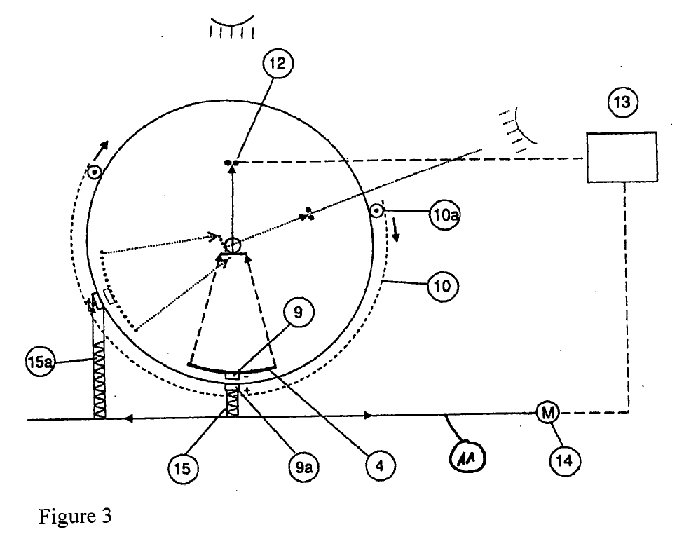

FIG. 3 schematically shows a further embodiment of a mechanism for tracking the circulating mirror,

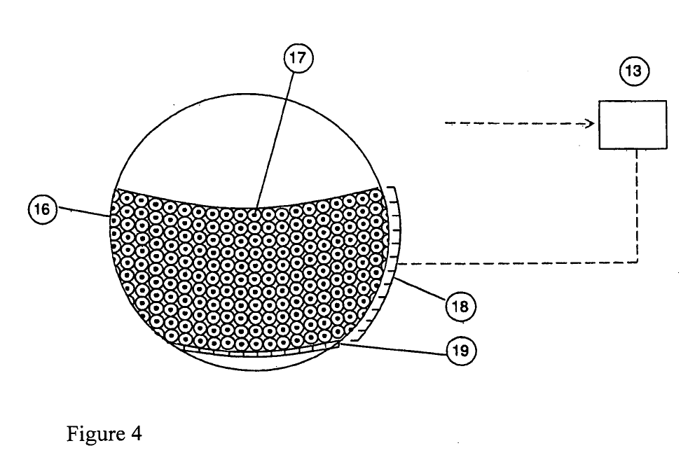

FIG. 4 schematically shows an alternative embodiment for a tracking system with small solenoids,

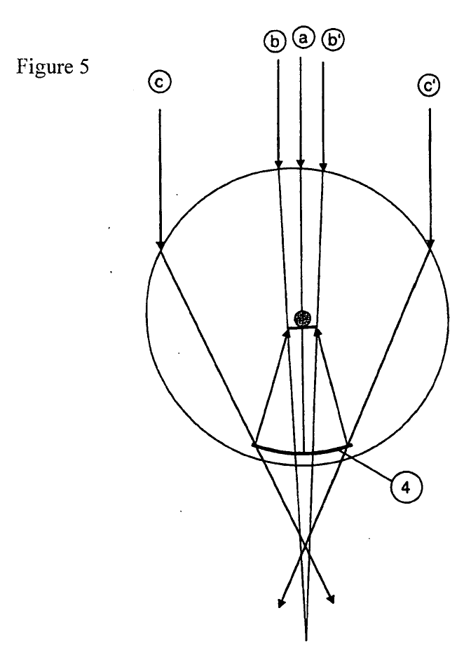

FIG. 5 schematically shows an overview of the path of the rays, and

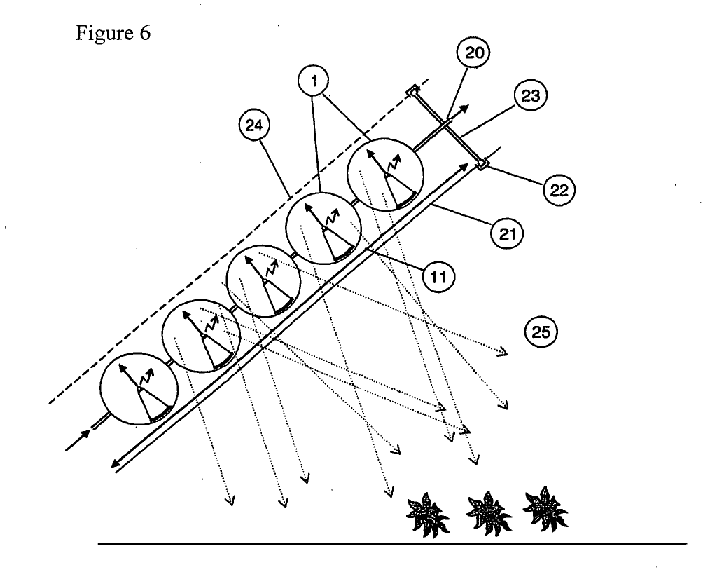

FIG. 6 schematically shows a combination of several spherical lens systems forming a roof surface.

The transparent hollow sphere 1 in FIG. 1 is filled, on the inside, with a transparent internal liquid filling 2. The transparent hollow sphere 1 is exposed to radiation from the sun, whereby, taking the moving sun 3 with its azimuth path 3a and its elevation path 3b as a starting point, the

radiation from the sun becomes a practically parallel radiation when it reaches the transparent hollow sphere 1. The parallel radiation hits the transparent hollow sphere 1 with a center ray 3c, which extends without any change in direction along the optical axis and thus through the sphere center M, and with two outer edge rays 3d, 3d′, which are broken and, in the plane of the circulating mirror 4, form a circular sectional plane penetrated by pre-concentrated light.

If the circulating mirror 4 is moved cardanically about the sphere center M in such a way that its normal line vector of the central point is identical to the optical axis of the central ray 3c, it follows the sun 3 precisely.

The shape of the circulating mirror 4, according to the caustic surface of the incident light of its projection plane, is chosen such that its focal point 5 is mapped in the sphere center M with the desired distribution of intensity. In single cases the desired shaping may be effected without a great deal of expense using modern ray tracing systems.

The circulating mirror 4 runs along the outer envelope of the transparent hollow sphere 1, while the sun 3 moves. The focal point 5 therefore is permanently returned back to the sphere center M and is stationary in this position. This is the reason why solar converters may be installed here, which merely rotate about their central point according to the azimuth position or elevation position of the sun.

The basic idea of the optical system in FIG. 1 consists in tracking the circulating mirror 4 being taken along inside the liquid-filled, stationary and transparent hollow sphere 1 and in shaping it in such a way that the pre-concentrated light in the transparent hollow sphere 1 is returned to a focal point 5 which lies in the central point M of the transparent hollow sphere 1.

To achieve this, a circular mirror having at least the diameter of the pre-concentrated sunlight at this point is moved cardanically about the sphere center M directly in front of the rear inner spherical cap in such a way that the normal line vector leading from the mirror center through the sphere center M is always aligned with the moving sun.

With the second embodiment described (see FIG. 2) a concentrator solar cell is used as solar converter 6. This is connected rigidly via struts 8 with the circulating mirror 4 following the sun and therefore moves cardanically about the sphere center M.

Both the struts 8 and a co-moved sun pointer 8a the tip of which is equipped with an azimuth sensor and an elevation sensor, consist of a transparent material having the same refractive index as the sphere liquid. The incident sun rays 3c, 3d, 3d′ pass the struts 8 without any optical impairment.

The same applies to the hollow strut 7 which provides for a connection to the outside through the outer wall of the sphere and protrudes as far as the sphere center M. There it is received by a cardan joint to which a solar energy converter named simply solar converter 6 is attached. Electrical input and output lines 7a lead through the liquid-filled stretch in the hollow strut 7 to the concentrator solar cell used in this case.

As a result, the solar cell thus surrounded on both sides by the optical medium is optically coupled without any losses not only due to the immersion but is also effectively cooled by the liquid. If the medium in the sphere is redirected and pumped to an external heat exchanger (not shown) available heat can be generated in addition to electrical current.

If the masses of the system rotating about the cardan joint and comprised of circulating mirror 4, solar converter 6 and struts 8 are well balanced, minimum forces are required for tracking the arrangement of the sun path since the optical liquid filling 2 inside the transparent hollow sphere 1 is of low viscosity apart from having the desired parameters as regards refractive index and spectrally selective transmissions. On the other hand the viscosity is high enough to dampen the movement thereby preventing the circulating mirror 4 from swinging past its required value position.

By mounting the dynamic lens system in a liquid inside the transparent hollow sphere (1) it is possible to make it move contactlessly using a magnetic field which is effective through the wall of the sphere. This is achieved by use of the outer permanent magnet 9a and the inner permanent magnet 9 which is attached centrally to the rear side of the circulating mirror 4, and which has opposite polarity or is shaped as a soft iron core.

The outer permanent magnet 9a is guided by a mechanism in a curved path which corresponds to the azimuth and elevation movement of the sun 3 and thereby takes the dynamic lens system including the circulating mirror 4 with it in the desired way, by means of magnetic coupling.

The tracking mechanism in FIG. 3 employs a mechanism for controlling the circulating mirror 4. Here the outer permanent magnet 9a is taken along by an external ring system 10 which travels around the sphere 1 on rollers 10a like a half shell. The necessary kinetic energy is transmitted by a connecting rod 11 which is moved by two motors 14 (shown in principle only) in x-direction and y-direction, i.e. corresponding to the azimuth and elevation movement of the sun.

Activation of the motors 14 is realized by signals sent to the motors 14 from a sunlight sensor 12 and a microelectronic device 13.

Since the distance of the surface of the sphere from the permanent magnet 9a continually changes as a function of the linear x- and y-movement, as does the tangent on the surface of the sphere to which the permanent magnet 9a shall adapt, this magnet is attached, on the one hand, to a spring 15 which adapts to the changing distance towards elongated shapes 15a. On the other hand, the outer permanent magnet 9a is rotatably mounted so that it orientates itself in the direction of the respective tangent. In order to minimize its friction forces on the surface of transparent sphere 1, it may be provided with a low-friction coating itself or with a roller.

In a further embodiment shown, tracking of the dynamic lens system is effected by a matrix of small solenoids 17 which are firmly attached to the spherical cap facing away from the sun (see FIG. 4).

The solenoids 17 are operated time-sequentially as a function of the control signals ascertained by the sun sensor and the downstream microelectronic device such that the inside lens system follows the path of the sun.

During the course of the year the image of the sun formed by the spherical lens system sweeps over an area 16 on the north side of the sphere facing away from the sun.

The small solenoids 17 cover the area 16 in rows and columns in a finely grained manner. The microprocessor 13 acted upon by the sun sensor activates, via electrical row distributors 18 and column distributors 19, the respectively correct solenoid whose magnetic field then takes the inner lens system along.

As regards the materials to be used for the hollow sphere and the liquid there exists a broad variety of choices.

The transparent hollow sphere 1 may, for example, be made of glass or transparent plastics.

Especially suited are fluoric polymers, in particular their FEP version, which in the present case (with liquid inside) transmits at least 98% of light across the entire solar spectrum, is light-resistant, self-cleaning and chemically quasi inert.

As regards the criteria for selecting the liquid explanations have already been given above.

Spherical lens systems only map the rays close to the optical axis onto a focus. The axis-remote rays, however, combine in a focal line in front of this focus. This is called spherical aberration.

FIG. 5 schematically shows how the spherical aberration is corrected by the contour of the circulating mirror 4.

A central ray a extends along the optical axis through the central point of the sphere and reaches free space without being deflected by the rear side of the sphere.

Two equidistant rays b, b′ close to the axis combine in the focal point.

Two equidistant rays c, c′ remote from the axis combine in front of the focal point.

If the circulating mirror 4 is to combine all incident rays in the central point its curvature in direction to the edge must increase.

Therefore the circulating mirror 4 is preferably shaped in such a way that it corrects the spherical aberration and/or generates a desired distribution of energy density in the mapping plane of the solar converter, for example a homogenous distribution of the light flow across photo-voltaic converters. It should be pointed out that a distribution of energy density which remains constant while the sun moves shall preferably fall within the scope of the invention, even if the invention specifies a “stationary focal point”.

The spherical lens system described comprising stationary spheres and an inner dynamic lens system utilizes the direct sunlight for converting it into electrical current or heat or for transporting the light via waveguides or for converting it photo-voltaically.

The diffuse light exits through the side of the sphere facing away from the sun insofar as it is not reflected back by the circulating mirror.

This characteristic is utilized by the plurality of spherical lens systems shown in FIG. 6, which form the semi-transparent roof surface—or generally an envelope for buildings, especially greenhouses. The plurality of optical systems comprising transparent spheres 1 are arranged here as an areal structure.

In earlier patent applications the inventor has described “envelopes” of this kind, where large-area Fresnel lens systems taken along underneath a protecting transparent envelope supply the greenhouse space with ideal diffuse light for growing plants, whilst, on the other hand, preventing it from overheating which is associated with direct light, and converting the light instead into usable energy, typically into electrical current. With the spherical lens system proposed these effects can be achieved using stationary structures which compared to the state of the art represents a big advantage.

This is especially true of small lightweight spheres. Modern triple-junction solar cells which nowadays achieve efficiencies of 40% when converting sunlight into electrical current, typically operate with a sunlight concentration of about a factor of c=500. At present they can be manufactured in sizes of approx. 1 mm². Spheres with a diameter of approx. 3 cm are suitable for this.

The spherically shaped optical systems shown in FIG. 6 are connected with each other via a fluid connecting line 20.

Connecting rods 11 form a tracking mechanism for the dynamic lens systems inside the transparent hollow sphere 1. A transparent disc or membrane 21 is arranged below the transparent hollow spheres 1. To this is coupled, via a strut system 22, 23, the sphere arrangement which is mechanically coupled to the fluid connecting line 20. Optionally an upper transparent disk or membrane 24 may be provided.

The stationary spherical lens arrangement serves as a semi-transparent roof which, in the illustrated case, produces electrical current and hot water and which, at the same time, provides the plants inside the greenhouse with any diffuse light 25 getting there.

If optical waveguides acting as light receivers decouple the concentrated light from the central points of the spheres, the spherical lens arrangement may also rest on a non-transparent base. The space below it may be lit, if required, via the light flow through the waveguides.

### SUMMARY

The invention relates to an optical system with a transparent sphere, in particular when filled with a transparent liquid.

Direct sunlight penetrating at the sunlit surface of the sphere is reflected by a circulating mirror on the opposite inner side of the hollow sphere such that the focal point of the radiation field is mapped in the central point of the hollow sphere.

Solar converters can thus be statically arranged in the central point of the hollow sphere and preferably comprise a rotating means in order to permanently keep them in ideal alignment with the concentrated sunlight.

1. Optical system with a transparent sphere (1), wherein the optical system comprises a dynamic lens system for concentrating moving sunlight at a locally static focal point (5).

2. Optical system according to claim 1, wherein a solar converter (6) is provided at the static focal point (5).

3. Optical system according to claim 2, wherein the solar converter (6) comprises a rotating means.

4. Optical system according to claim 3, wherein the rotating means comprises a connecting strut (8) to the dynamic lens system.

5. Optical system according to claim 1, wherein a tracking device is provided for the dynamic lens system.

6. Optical system according to claim 1, wherein the transparent sphere (1) is stationary.

7. Optical system according to claim 5, wherein the tracking device is adjusted in such a way that it aligns a normal line vector of the dynamic lens system with the sun (3).

8. Optical system according to claim 5, wherein the tracking device is set in such a way that it guides the dynamic lens system, with regard to the incident sunlight, beyond a central point M of the transparent sphere (1).

9. Optical system according to claim 1, wherein a normal line vector points from the dynamic lens system to a central point (M) of the transparent sphere (1).

10. Optical system according to claim 1, wherein the static focal point (5) lies within the transparent sphere (1).

11. Optical system according to claim 10, wherein the static focal point (5) lies in a central point (M) of the transparent sphere (1).

12. Optical system according to claim 1, wherein the dynamic lens system comprises a circulating mirror (4).

13. Optical system according to claim 1, wherein the dynamic lens system has a circular circumference.

14. Optical system according to claim 1 comprising a transparent sphere (1) and a dynamic lens system with a tracking device, wherein the tracking device comprises a contactless drive, in particular an outer magnet (9a) and an inner magnet (9).

15. Optical system according to claim 1, wherein the tracking device comprises a shell.

16. Optical system according to claim 1, wherein the tracking device comprises a plurality of controllable outer magnets, in particular in the form of solenoids (17).

17. Optical system according to claim 1 comprising a transparent sphere (1), wherein the transparent sphere (1) comprises a dynamic lens system in its inside, which together with dynamic fittings has a center of gravity which lies in a central point (M) of the transparent sphere (1).

18. Optical system according to claim 1, wherein the transparent sphere (1) is filled with a liquid (2).

19. Optical system according to claim 18, wherein a fitting in the transparent sphere (1) has an optical refractive index which corresponds to that of the liquid (2).

20. Optical system according to claim 1 comprising a transparent sphere (1), wherein the transparent sphere (1) is filled with a liquid (2), wherein the optical system comprises a lens system for concentrating moving sunlight at a solar converter (6), and wherein the solar converter (6) is surrounded by the liquid (2).

21. Optical system according to claim 1, wherein a feed line to an external heat exchanger is provided.

22. Optical system according to claim 1, wherein the dynamic lens system comprises a mirror deviating from the spherical shape.

23. Use of the optical system according to claim 1 for utilizing direct sunlight and for allowing the passage of diffuse sunlight.

24. Use of a plurality of optical systems according to claim 1 as an outer envelope of a building, in particular a greenhouse.

25. Use according to claim 24, wherein a plurality of tracking devices have one common mechanical power generator.

26. Use according to claim 24, wherein the transparent spheres (1) are connected with each other in such a way that liquid (2) can be redirected in order to dissipate heat from the transparent spheres (1) in a purposeful manner.
